(19) United States
(12) Patent Application Publication
(10) Pub. No.: US 2026/0108898 A1
(43) Pub. Date: Apr. 23, 2026

(54) METHOD FOR MANUFACTURING SEMICONDUCTOR DEVICE AND SEMICONDUCTOR MANUFACTURING APPARATUS

(71) Applicant: Kioxia Corporation, Tokyo (JP)

(72) Inventors: Chihiro SAKAMOTO, Kuwana Mie (JP); Yusuke KONDO, Yokkaichi Mie (JP)

(21) Appl. No.: 19/070,478

(22) Filed: Mar. 4, 2025

(30) Foreign Application Priority Data
Oct. 17, 2024 (JP) 2024-181887

(51) Int. Cl. B05B 3/10; H01L 21/311; H10B 43/27

(52) U.S. Cl. CPC B05B 3/1007; H10B 43/27; H10P 50/283

(57) ABSTRACT

According to one embodiment, a method for manufacturing a semiconductor device includes: preparing a workpiece formed with a recess; supplying a material containing halogen elements in a liquid form into the recess; cooling the material supplied in the liquid form to solidify the material supplied in the liquid form; and etching the recess using plasma while the material solidified is in the recess.

### CROSS-REFERENCE TO RELATED APPLICATION(S)

This application is based upon and claims the benefit of priority from Japanese Patent Application No. 2024-181887, filed Oct. 17, 2024, the entire contents of which are incorporated herein by reference.

### FIELD

Embodiments described herein relate generally to a method for manufacturing a semiconductor device and a semiconductor manufacturing apparatus.

### BACKGROUND

When a semiconductor device such as a three-dimensional semiconductor memory is manufactured, a recess may be formed at a workpiece by etching. In forming the recess, a bottom portion thereof may have a shrunk shape, and thus etching may be additionally performed to widen the bottom portion. At this time, the etching selectivity for the bottom portion may be lower than that for a surface of the recess.

### BRIEF DESCRIPTION OF THE DRAWINGS

FIG. 1 is a cross-sectional view illustrating a structure of a semiconductor device according to a first embodiment.

FIGS. 2A, 2B, 3A, 3B, 4A, 4B, 5A, and 5B are each a cross-sectional view illustrating a method for manufacturing the semiconductor device according to the first embodiment.

FIG. 6 is a view illustrating a configuration example of a semiconductor manufacturing apparatus according to a second embodiment.

### DETAILED DESCRIPTION

Embodiments provide a method for manufacturing a semiconductor device and a semiconductor manufacturing apparatus capable of selectively processing a bottom portion of a hole by reactive ion etching.

In general, according to one embodiment, a method for manufacturing a semiconductor device includes: preparing a workpiece formed with a recess; supplying a material containing halogen elements in a liquid form into the recess; cooling the material supplied in the liquid form to solidify the material supplied in the liquid form; and etching the recess using plasma while the material solidified is in the recess.

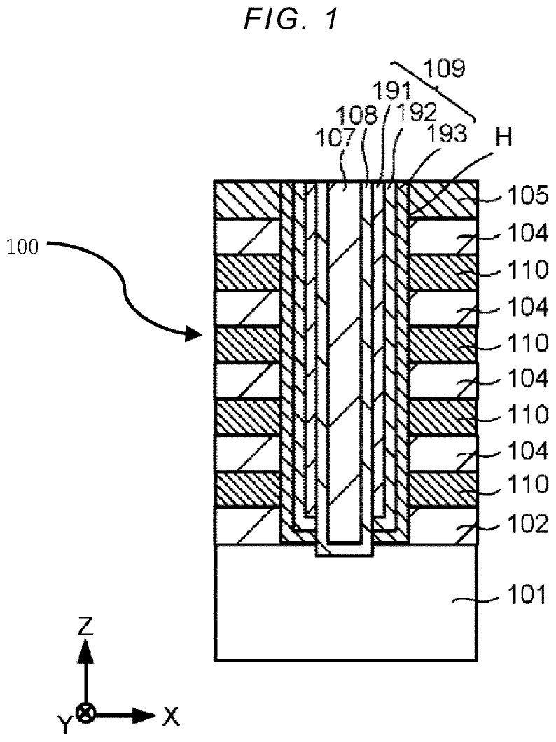

Embodiments will be described below with reference to the accompanying drawings. In FIG. 1 to FIG. 6, the same or similar components are denoted by the same reference signs, and duplicate explanations are omitted. It should be noted that the present disclosure is not limited to the embodiments.

### First Embodiment

FIG. 1 is a cross-sectional view illustrating a structure of a semiconductor device of a first embodiment. The semiconductor device of FIG. 1 is, for example, a three-dimensional NAND memory.

FIG. 1 illustrates a semiconductor device 100 of the first embodiment, and illustrates a part of an X-Z cross-section of the semiconductor device 100 including an X-axis and a Z-axis which is orthogonal to the X-axis and orthogonal to a Y-axis. As illustrated in FIG. 1, the semiconductor device 100 includes a substrate 101, a lower layer 102 provided on the substrate 101, insulation layers 104 and conductive layers 110 alternately stacked above the lower layer 102, an upper layer 105, a core insulation film 107, a semiconductor channel layer 108, and a memory film 109.

The memory film 109 includes a tunnel insulation film 191, a charge storage layer 192, and a block insulation film 193. The memory film 109, the semiconductor channel layer 108, and the core insulation film 107 are formed in this order in a memory hole H to be described below, and function as a memory layer for a memory cell.

An example of the substrate 101 is a wafer including a semiconductor substrate such as a silicon (Si) substrate.

An example of the lower layer 102 is an insulation layer such as a silicon oxide (SiO2) film or a silicon nitride (SiN) film, or a conductive layer formed between insulation films. An example of the insulation layer 104 is a silicon oxide film.

An example of the upper layer 105 is an insulation film such as a silicon oxide film or a silicon nitride film, or a conductive layer formed between insulation films.

As the core insulation film 107, for example, a silicon oxide film may be used.

As the semiconductor channel layer 108, for example, a polysilicon film may be used.

As the tunnel insulation film 191, for example, a film stack including a silicon oxide film and a silicon oxynitride (SiON) film may be used. As the charge storage layer 192, for example, a silicon nitride film may be used. As the block insulation film 193, for example, a silicon oxide film may be used.

A method for manufacturing a semiconductor device of the first embodiment will be described. The method for manufacturing a semiconductor device according to the first embodiment includes forming the memory hole H in which the memory layer described with reference to FIG. 1 is formed.

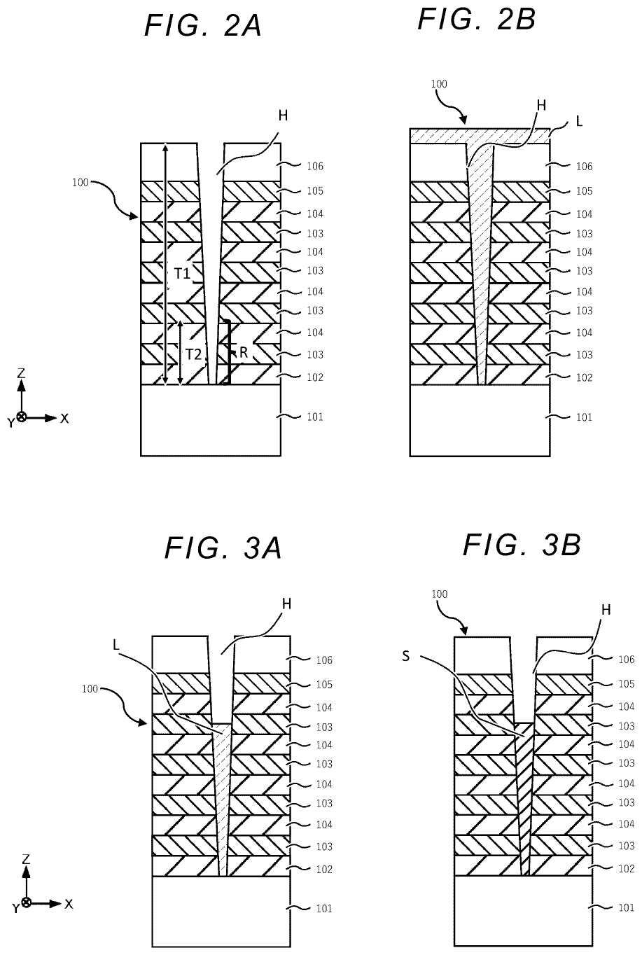

FIG. 2A to FIG. 6 are cross-sectional views illustrating the method for manufacturing a semiconductor device of the first embodiment.

First, the semiconductor device 100 formed with the memory hole H is prepared. FIG. 2A illustrates the semiconductor device 100 with the memory hole H formed by reactive ion etching (RIE). The memory hole H is formed by putting the semiconductor device 100 formed with a film stack into a known dry etching chamber or a known dry etching apparatus and performing RIE. The etching is performed at a low temperature of, for example, 0° C. or less, using, for example, carbon fluoride gas, fluorohydrocarbon gas, or hydrogen fluoride gas. In the semiconductor device 100 illustrated in FIG. 2A, the lower layer 102 is formed on the substrate 101, and a film stack including a plurality of sacrificial layers 103 and a plurality of insulation layers 104 in an alternating manner is formed on the lower layer 102. Further, the upper layer 105 is formed on the film stack, and a hard mask layer 106 is formed on the upper layer 105.

An example of the sacrificial layer 103 is a silicon nitride film.

An example of the hard mask layer 106 is a carbon film formed by a chemical vapor deposition (CVD) method.

When the memory hole H is formed by RIE, the bottom portion of the memory hole H may have a constricted shape, as illustrated in FIG. 2A. This occurs when a by-product generated by etching at the upper or middle portion of the memory hole H adheres to a side wall of the memory hole H and prevents the processing of the bottom portion. The constricted shape of the bottom portion of the memory hole H is, for example, such a shape that the diameter of the memory hole H in any portion of a region R that extends to a height T2, which is ⅕ or less of a total height T1 of the memory hole H, is smaller than that of other regions. Here, the bottom portion refers to the region R. The constricted shape of the bottom portion of the memory hole H is, for example, such a shape that the diameter of the memory hole H sequentially decreases from the upper portion toward the lower portion. Here, the bottom portion refers to a region whose diameter is equal to or less than a diameter set for the memory hole H. The memory hole H is an example of a recess.

Next, a material containing halogen elements is supplied to the memory hole H to form a liquid layer L, as illustrated in FIG. 2B. A method for forming the liquid layer L is described below in the next paragraph.

After RIE, the semiconductor device 100 with the memory hole H whose bottom portion is constricted, is taken out from the dry etching chamber or the dry etching apparatus. Then, the semiconductor device 100 is placed on a spin coater table, and the semiconductor device 100 is fixed to the spin coater table by suction.

Next, a material containing halogen elements in a form of liquid is dripped onto the semiconductor device 100 that has been fixed to the spin coater table. The halogen elements are, for example, fluorine (F) or chlorine (Cl), and the material containing the halogen elements contains, for example, at least one of IF₅, BrF₃, BrF₅, IFCl, or CₓF_{y} (where C is carbon; x and y are integers; and x is 5 or greater). CxFy contains, for example, at least one of C₅F₁₀, C₅F₁₂, C₆F₁₄, C₇F₁₆, C₈F₁₈, or C₉F₂₀. For example, C₅F₁₀ has a higher melting point than other CₓF_{y}'s, and thus is more preferable. When the material containing the halogen elements is IF₅, BrF₃, BrF₅, C₅F₁₀, C₅F₁₂, C₆F₁₄, C₇F₁₆, C₈F₁₈, or C₉F₂₀, each of which is a liquid at normal temperature and pressure, the treatment illustrated in FIG. 2B is performed at normal temperature and pressure. On the other hand, when the material containing the halogen elements is IFCl which is not a liquid at a normal temperature (25° C.), the material containing the halogen elements may be liquefied by adjustment such as increasing the temperatures of the material containing the halogen elements and the semiconductor device 100.

Next, spin coating is performed. That is, the spin coater table is rotated in a state in which the liquid layer L has been dripped onto the semiconductor device 100. Thereby, the material containing the halogen elements can be supplied into the memory hole H and the excess liquid layer L can be removed from the surface layer of the semiconductor device 100, as illustrated in FIG. 3A.

Next, as illustrated in FIG. 3B, the semiconductor device 100 in which the material containing the halogen elements is present as the liquid layer L in the memory hole H is cooled so that the material containing the halogen elements is solidified to form a solid layer S. Solidifying the material containing the halogen elements has advantages of increasing the amount of the halogen elements per volume and facilitating adjustment of the height of the solid layer S to be described below. In addition, by solidification, the reactivity of the halogen elements in a liquid phase can be reduced, thereby preventing unnecessary etching until a second treatment to be described below. The cooling of the semiconductor device 100 is performed, for example, such that the semiconductor device 100 is cooled to a temperature equal to or lower than the freezing point of the liquid containing the halogen elements using a chiller used for cooling a stage. It should be noted that, when the liquid layer L has high viscosity and thus is not required to be solidified, it is not necessarily required to obtain the solid layer S, and the liquid layer L may be maintained as-is.

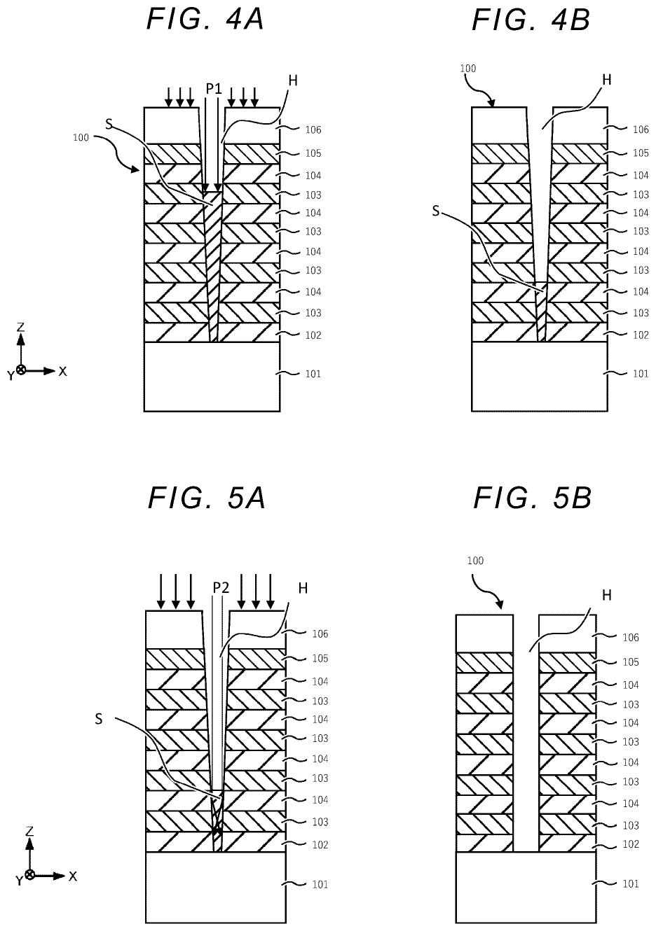

Next, as illustrated in FIG. 4A, a first treatment for adjusting the solid layer S to a desired height is performed. The first treatment is performed after the semiconductor device 100 is brought back from the spin coater table to the dry etching chamber or the dry etching apparatus.

The first treatment is performed using gas G1. The gas G1 is, for example, noble gas and contains argon or helium. The gas G1 is, for example, oxygen. The gas G1 is noble gas when the material containing the halogen elements is IF₅, BrF₃, BrF₅, or IFCl, or oxygen when the material containing halogen elements is CₓF_{y}. In the first treatment, for example, the solid layer S is irradiated with plasma P1 generated by applying a low voltage to the gas G1, whereby the height of the solid layer S is adjusted to a target height. The target height is, for example, a height of the region R in which the diameter of the memory hole H is constricted. As the low voltage, for example, a voltage of a few kV to a few tens of kV is used.

FIG. 4B is a view of the memory hole H in which the solid layer S is adjusted to the target height by the first treatment. In the first treatment, for example, because the applied voltage is low, the probability that the material contained in the solid layer S obtains energy required to etch the lower layer 102, the sacrificial layer 103, or the insulation layer 104 is low. Thus, the height of the solid layer S can be adjusted with little change in the diameter of the memory hole H.

Next, the second treatment is performed to widen the bottom portion of the memory hole H by partially etching the sacrificial layers 103 and the insulation layers 104.

The second treatment is performed using gas G2. The gas G2 is, for example, noble gas. The gas G2 contains, for example, argon or helium. The gas G2 may be the same gas as the gas G1.

After the adjustment of the height of the solid layer S, in the second treatment, the memory hole H is etched using plasma P2, which is generated by applying a high voltage to the gas G2, in a state in which the solid layer S is present at the bottom portion, as illustrated in FIG. 5A. As the high voltage, for example, a voltage of a few tens of kV to a few hundreds of kV is used.

It is desirable to perform the second treatment while cooling the semiconductor device 100 so as to prevent the solid layer S from melting. For example, when IF5 is used as a halogen material, it is preferable to perform the second treatment at a temperature equal to or lower than 9.4° C. which is the melting point of IF5. In addition, it is preferable to appropriately provide cooling to a temperature at which the efficiency of the etching increases (e.g., 0° C. or lower).

As a result, the memory hole H whose bottom portion is widened as illustrated in FIG. 5B is formed. Since the solid layer S, which is the material containing the halogen elements, is present, the halogen elements are supplied to the bottom portion of the memory hole H as etchant. Therefore, the bottom portion of the memory hole H can be widened even in etching by the plasma P2 generated from the gas G2 which does not contain the halogen elements. That is, the constricted shape of the bottom portion of the memory hole H is improved, and the memory hole H having a substantially equal diameter between the upper portion and the bottom portion of the memory hole H as illustrated in FIG. 5B is formed.

The first treatment and the second treatment may be repeated until the depth of the memory hole H and the area of the bottom portion reach desired states.

In addition, over-etching may be performed after these steps.

After the memory hole H is formed, the memory film 109 and the semiconductor channel layer 108 are formed in the memory hole H, and the sacrificial layer 103 is removed from a groove (not illustrated) and replaced with the conductive layer 110, whereby the semiconductor device 100 illustrated in FIG. 1 is manufactured.

In this way, the method for manufacturing a semiconductor device of the first embodiment is provided.

According to the method for manufacturing a semiconductor device according to the first embodiment, the bottom portion of the hole can be widened by performing etching in a state in which the material containing the halogen elements is present at the bottom portion of the hole. According to this method, it is possible to provide an etching method with a higher etching selectivity for a mask layer on the surface of a semiconductor device as compared with plasma etching performed for the purpose of widening the bottom portion of the hole in a state in which the material containing halogen elements is not present at the bottom portion of the hole. Accordingly, the thickness of the mask layer required can be reduced, and further, the need for a step of protecting the mask layer is eliminated. In addition, since the material containing halogen elements is supplied to the semiconductor device in a form of liquid in which the density of the halogen elements is higher than in a form of gas, more halogen elements can be supplied to the bottom portion of the hole. Furthermore, since a time required for changing to a solid phase is shorter than in a case of supplying in a gas phase and thus the reactivity can be easily reduced, unintended reaction can be prevented. In addition, since the height of the solid layer S is adjusted by the first treatment performed at a low voltage, etching in unintended regions can be prevented.

### Second Embodiment

A semiconductor manufacturing apparatus and a method for manufacturing a semiconductor device according to a second embodiment will be described below.

In the first embodiment, the formation of the memory hole H and the formation of the liquid layer L are described as being performed in separate chambers or apparatuses, but in the second embodiment, they are performed in the same chamber. The description of the parts that are common with the first embodiment is omitted.

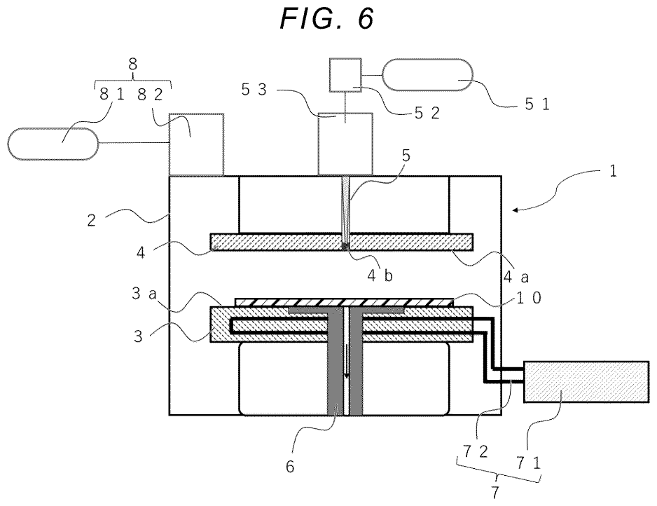

FIG. 6 is a view illustrating a configuration example of a semiconductor manufacturing apparatus 1 that may be used in a method for manufacturing a semiconductor device according to the second embodiment. As illustrated in FIG. 6, the semiconductor manufacturing apparatus 1 includes a treatment chamber 2 (i.e., chamber), a lower electrode 3, an upper electrode 4, a liquid supply nozzle 5, a spin coater table 6, a cooling apparatus 7, and a gas supply unit 8.

The treatment chamber 2 is a space in which a workpiece 10 can be etched by RIE using plasma (i.e., plasma etching). An example of the workpiece 10 is the semiconductor device 100 illustrated in FIG. 1. In the treatment chamber 2, a hole (i.e., a recess) is formed in the workpiece 10 by etching. The hole can also be referred to as an opening. The treatment chamber 2 may include a door (gate) for putting in and taking out the workpiece 10.

The lower electrode 3 has a function as a placement base for placing the workpiece 10 thereon. The lower electrode 3 includes a surface 3a which is a placement surface for the workpiece 10. The semiconductor manufacturing apparatus 1 may include an electrostatic chuck for holding the workpiece 10 on the surface 3a.

The upper electrode 4 includes a surface 4a and an opening 4b which penetrates the upper electrode 4 so as to introduce a liquid into the treatment chamber 2.

The liquid supply nozzle 5 is connected to a material supply source 51, a temperature adjustment unit 52, and a mass flow controller 53. The liquid is supplied from the material supply source 51 to the workpiece 10 through the liquid supply nozzle 5.

The material supply source 51 stores a material that is a first liquid. The temperature adjustment unit 52 includes a mechanism that can adjust the temperature of a material containing halogen elements, such as a cooler or a heater, for example.

The first liquid is a liquid material containing halogen elements. The liquid material containing halogen elements is, for example, IF₅, BrF₃, or IFCl. The material containing halogen is, for example, CₓF_{y} (where x and y are integers). CxFy contains, for example, at least one of C₅F₁₀, C₅F₁₂, C₆F₁₄, C₇F₁₆, C₈F₁₈, or C₉F₂₀.

The mass flow controller 53 regulates the flow rate of the first liquid which is introduced into the treatment chamber 2 from the material supply source 51.

The spin coater table 6 includes a wafer suction table 61, and can place thereon the workpiece 10. The spin coater table 6 is configured to be driven up and down and rotatable around a vertical axis including the center of concentric circles.

The spin coater table 6 is surrounded by the lower electrode 3 in a plan view. That is, the spin coater table 6 penetrates the lower electrode 3 at the center thereof in the vertical direction.

The cooling apparatus 7 includes a chiller 71 and a refrigerant pipe 72 which is provided inside the lower electrode 3. The chiller 71 cools the workpiece 10 on the lower electrode 3 by circulating a refrigerant through the refrigerant pipe 72.

The gas supply unit 8 includes a gas supply source 81 such as a cylinder cabinet, and a mass flow controller 82. The gas supply unit 8 supplies gas from the gas supply source 81 to the treatment chamber 2.

The gas supply source 81 stores the gas G1 and the gas G2. The gas G1 and the gas G2 are separately stored in containers such as gas cylinders.

The mass flow controller 82 regulates the flow rate of each of the gas G1 and the gas G2 which is introduced into the treatment chamber 2 from the gas supply source 81.

Next, the method for manufacturing a semiconductor device according to the second embodiment will be described.

In the second embodiment, as in the first embodiment, the memory hole H is formed (FIG. 2A), and then the semiconductor device 100 is put into the semiconductor manufacturing apparatus 1 of the present embodiment. After that, as in the first embodiment, the material containing halogen elements is supplied, and the first treatment for adjusting the material containing halogen elements to a desired height and the second treatment for etching the bottom portion of the memory hole H are performed.

More specifically, the semiconductor device 100 in which the memory hole H is formed is put into the treatment chamber 2, and placed on the spin coater table 6 to be subjected to spin coating with the material containing halogen elements. In a state in which the semiconductor device 100 is placed on the spin coater table 6, the spin coater table 6 is rotated, and the material containing halogen elements in a form of liquid is supplied from the liquid supply nozzle 5 to the semiconductor device 100. When the material containing halogen elements is solid at normal temperature and pressure, the material containing halogen elements is heated by the temperature adjustment unit 52 to be liquefied and is supplied to the semiconductor device 100 (FIG. 3A).

Next, the semiconductor device 100 is cooled by the cooling apparatus 7, so that the material containing halogen elements in a form of liquid is solidified. Through this operation, the material containing halogen elements in a form of solid formed at the bottom portion of the memory hole H becomes the solid layer S (FIG. 3B).

Next, the gas G1 is supplied from the gas supply unit 8 to the treatment chamber 2. For example, plasma is generated by applying a low voltage to the upper electrode 4 and the lower electrode 3, and the solid layer S is irradiated with the generated plasma, so that the solid layer S is adjusted to a desired height (FIG. 4A). Then, a purge process of releasing the gas G1 from the treatment chamber 2 may be performed.

Next, the gas G2 is supplied from the gas supply unit 8 to the treatment chamber 2. Plasma is generated by applying a high voltage to the gas G2 from the upper electrode 4 and the lower electrode 3. In a state in which the solid layer S is present at the bottom portion of the memory hole H, the bottom portion is etched by using the plasma so that the bottom portion of the memory hole H is widened (FIG. 5B).

Then, the memory film 109, the semiconductor channel layer 108, and the core insulation film 107 are formed in the memory hole H in this order, whereby the semiconductor device illustrated in FIG. 1 is manufactured.

According to the method for manufacturing a semiconductor device according to the second embodiment, as compared to the first embodiment, the transfer between the dry etching chamber or device and the spin coater table can be reduced, and thus the temperature of the semiconductor device can be easily maintained constant, and the material containing halogen elements solidified can be prevented from melting.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, the method comprising:
preparing a workpiece formed with a recess;
supplying a material containing halogen elements in a liquid form into the recess;
cooling the material supplied in the liquid form to solidify the material supplied in the liquid form; and
etching the recess using plasma while the material solidified is in the recess.

2. The method according to claim 1, wherein the etching is performed using a noble gas.

3. The method according to claim 2, wherein the etching is performed using argon or helium.

4. The method according to claim 1, wherein the material containing halogen elements contains at least one of IF₅, BrF₃, BrF₅, IFCl, or CₓF_{y} (where x and y are integers and x≥5).

5. The method according to claim 1, wherein the cooling is performed at a temperature equal to or lower than a freezing point of the material.

6. The method according to claim 1, wherein the material containing halogen elements contains at least one of C₅F₁₀, C₅F₁₂, C₆F₁₄, C₇F₁₆, C₈F₁₈, or C₉F₂₀.

7. The method according to claim 1, wherein the material containing halogen elements is supplied in the liquid form by spin coating that includes dripping the material in the liquid form onto the workpiece placed on a rotating table and rotating the rotating table.

8. The method according to claim 1, further comprising:
forming a memory film in the recess after the etching is performed, the memory film including a tunnel insulation film, a charge storage layer, and a block insulation film.

9. A method for manufacturing a semiconductor device, the method comprising:
preparing a workpiece formed with a recess;
forming a first layer in the recess by supplying a material containing halogen elements into the recess;
irradiating the first layer with plasma generated from first gas by applying a first voltage to the first gas, to adjust a height of the first layer; and
etching the recess after the height of the first layer has been adjusted while the first layer is in the recess, using plasma generated from second gas by applying a second voltage higher than the first voltage to the second gas.

10. The method according to claim 9, wherein
supplying the material containing halogen elements includes supplying the material in a liquid form, and solidifying the material in the liquid form by cooling, and
the etching is performed while the material is in a solid form.

11. The method according to claim 10, wherein the material containing halogen elements is supplied in the liquid form by spin coating that includes dripping the material in the liquid form onto the workpiece placed on a rotating table and rotating the rotating table.

12. The method according to claim 9, wherein the first gas and the second gas are each a noble gas.

13. The method according to claim 9, wherein the material containing halogen elements contains at least one of IF₅, BrF₃, BrF₅, IFCl, or CₓF_{y} (where x and y are integers and x≥5).

14. The method according to claim 9, wherein the material containing halogen elements contains at least one of C₅F₁₀, C₅F₁₂, C₆F₁₄, C₇F₁₆, C₈F₁₈, or C₉F₂₀.

15. The method according to claim 9, further comprising:
forming a memory film in the recess after the etching is performed, the memory film including a tunnel insulation film, a charge storage layer, and a block insulation film.

16. A semiconductor manufacturing apparatus comprising:
a treatment chamber configured to accommodate a workpiece;
a rotatable spin coater table on which the workpiece is to be placed;
a lower electrode surrounding the spin coater table;
an upper electrode disposed above the spin coater table and the lower electrode;
a liquid supply nozzle configured to supply liquid to the workpiece;
a cooling apparatus including a cooling pipe disposed inside the lower electrode; and
a gas supply source connected to the treatment chamber.

17. The semiconductor manufacturing apparatus according to claim 16, wherein the rotatable spin coater table is arranged within the treatment chamber.

18. The semiconductor manufacturing apparatus according to claim 16, further comprising
a material supply source connected to the liquid supply nozzle and configured to store a material, and
a cooler or a heater connected to the liquid supply nozzle and configured to adjust a temperature of the material.

19. The semiconductor manufacturing apparatus according to claim 16, wherein the lower electrode partially supports the workpiece when the workpiece is placed on the spin coater table.

20. The semiconductor manufacturing apparatus according to claim 16, wherein the workpiece, when placed on the spin coater table, is contained entirely within a region that is between the upper electrode and the lower electrode.
